(19) United States
(12) Patent Application Publication
(10) Pub. No.: US 2026/0070934 A1
(43) Pub. Date: Mar. 12, 2026

(54) TRANSITION METAL CLUSTER COMPOUND, PHOTOSENSITIVE COMPOSITION, PATTERN FORMING METHOD, AND METHOD FOR PRODUCING SUBSTRATE

(71) Applicant: Mitsubishi Chemical Corporation, Tokyo (JP)

(72) Inventors: Keishi Yamamoto, Tokyo (JP); Shigeki Hattori, Tokyo (JP); Kazuhiro Nagayama, Tokyo (JP); Akane Kato, Tokyo (JP); Ellie Iwasaki, Tokyo (JP)

(73) Assignee: Mitsubishi Chemical Corporation, Tokyo (JP)

(21) Appl. No.: 19/390,775

(22) Filed: Nov. 17, 2025

Related U.S. Application Data
(63) Continuation of application No. PCT/JP2024/017881, filed on May 15, 2024.

(30) Foreign Application Priority Data
May 22, 2023 (JP) 2023-083714

(51) Int. Cl. C07F 7/28; G03F 7/00; G03F 7/004; G03F 7/32

(52) U.S. Cl. CPC C07F 7/28; G03F 7/0042; G03F 7/325; G03F 7/70033

(57) ABSTRACT

An object of the present invention is to provide a transition metal cluster compound by which miniaturization of a circuit pattern can be realized; a photosensitive composition containing the transition metal cluster compound; and a pattern forming method using the photosensitive composition. The transition metal cluster compound is characterized by including 2 or more and 20 or less transition metal atoms and two or more types of carboxy ligands, wherein at least one type of the carboxy ligands includes an alicyclic structure having a double bond.

### CROSS-REFERENCE TO RELATED APPLICATIONS

This patent application is a bypass continuation of International Application No. PCT/JP2024/017881, filed on May 15, 2024, and which claims the benefit to Japanese Patent Application No. 2023-083714, filed on May 22, 2023, each of which are incorporated by reference in their entirety.

### BACKGROUND OF THE INVENTION

### Field of the Invention

The present invention relates to a transition metal cluster compound suitable for use in ultra micro-lithography processes such as the production of VLSI and high-capacity microchips and in other photofabrication processes; a photosensitive composition containing the transition metal cluster compound; and a pattern forming method using the photosensitive composition.

### Description of Related Art

In a process for producing a semiconductor device, microfabrication is carried out through lithography using a photoresist composition.

In semiconductor photolithography, according to Moore's law, circuit patterns are becoming smaller in association with the miniaturization of semiconductor devices, and further miniaturization is desired.

The development of photolithography is largely due to a shortening of the wavelength of the light source of an exposure apparatus and to the development of new photoresists in association therewith. Photoresists must satisfy all the requirements of high resolution, low roughness, and high sensitivity. Resists in the related art are photosensitive compositions containing a photoacid generator based on an organic polymer, and are called chemically amplified resists. Such resists cause a chemical reaction to proceed while being accompanied by the diffusion of acid, but the acid diffusion process causes line edge roughness (LER), which can result in a decrease in resolution. Therefore, it is considered that such resists cannot adapt to an ultra-fine pattern.

Therefore, in recent years, non-chemically amplified photoresists (hereinafter referred to as metal-containing resists) composed mainly of a compound containing a metal element such as Zn or Sn have been proposed. In the metal-containing resist, the metal component itself is a photosensitive substance and functions as a base material. Such metal-containing resists are expected to be used as next-generation resist materials for forming even finer pattern structures since acid diffusion is not involved, and thus the line edge roughness can be improved. In fact, it has been reported that fine patterns can be formed with a next-generation exposure apparatus using extreme ultraviolet light (EUV light).

For example, Patent Literatures 1 to 5 and Non-Patent Literatures 1 to 3 described below disclose methods for forming resist patterns using extreme ultraviolet light (EUV light), electron beams, or the like.

### CITATION LIST

### Patent Literature

Patent Literature 1: JP 2015-108781 A
Patent Literature 2: JP 2001-072716 A
Patent Literature 3: JP 2017-173537 A
Patent Literature 4: JP 2012-185484 A
Patent Literature 5: JP 2021-102604 A

### Non-Patent Literature

Non-Patent Literature 1: Minoru Toriumi, etc., Proc. SPIE, 9779 (2016) 97790G
Non-Patent Literature 2: Lianjia Wu, etc., Proc. SPIE, 10957 (2019) 109570B
Non-Patent Literature 3: Neha Thakur, etc., Proc. SPIE, 10957 (2019) 10957D

### SUMMARY OF THE INVENTION

### Technical Problem

As described above, metal-containing resists are expected to be used as resist materials that can adapt to ultra-fine patterns. However, metal-containing resists easily react with oxygen or moisture in air, and thus are problematic in terms of storage stability and developability.

Accordingly, an object of the present invention is to develop a metal-containing resist that is not easily affected by the storage environment or handling conditions, and to provide a photosensitive composition containing the metal-containing resist, as well as a pattern forming method using the photosensitive composition, and a method for producing a substrate using the pattern forming method.

### DETAILED DESCRIPTION OF THE INVENTION

The present invention includes the following aspects [1] to [16].

[1] A transition metal cluster compound containing 2 or more and 20 or less transition metal atoms and two or more types of carboxy ligands, wherein at least one type of the carboxy ligands comprises an alicyclic structure having a double bond.

[2] The transition metal cluster compound according to [1], wherein the at least one type of the carboxy ligands including an alicyclic structure having a double bond is a ligand represented by the following General Formula (1):

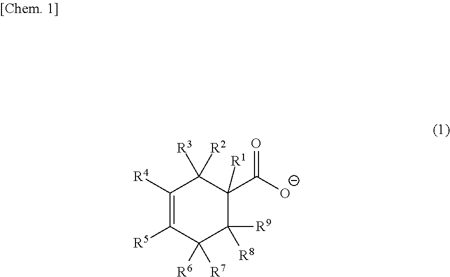

(in Formula (1), R¹ represents hydrogen, a halogen, a heteroatom-containing group, or a hydrocarbon group, and R² to R⁹ each independently represent hydrogen, a halogen, a heteroatom-containing group, or an organic group).

[3] The transition metal cluster compound according to [1] or [2], wherein the at least one type of the carboxy ligands including an alicyclic structure having a double bond is a ligand represented by the following General Formula (2):

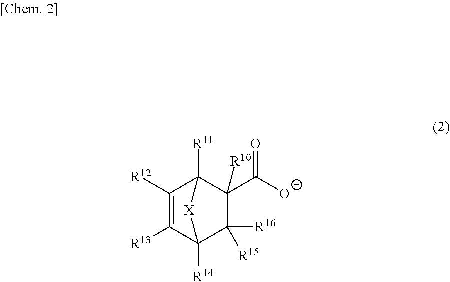

(in Formula (2), R¹⁰ represents hydrogen, a halogen, a heteroatom-containing group, or a hydrocarbon group, and R¹¹ to R¹⁶ each independently represent hydrogen, a halogen, a heteroatom-containing group, or an organic group; and X represents oxygen or an alkyl bridge).

[4] The transition metal cluster compound according to any of [1] to [3], wherein one type of the two or more types of carboxy ligands is the carboxy ligand including an alicyclic structure having a double bond and is represented by General Formula (1) or General Formula (2), and another one type of the two or more types of carboxy ligands comprises a carboxy ligand having a saturated hydrocarbon group.

[5] The transition metal cluster compound according to any of [1] to [3], wherein one type of the two or more types of carboxy ligands is the carboxy ligand including an alicyclic structure having a double bond and is represented by General Formula (1) or General Formula (2), and another one type of the two or more types of carboxy ligands comprises a carboxy ligand having a branched saturated hydrocarbon group.

[6] The transition metal cluster compound according to any of [1] to [5], wherein the transition metal atoms are selected from zirconium, hafnium, and titanium.

[7] A method for producing the transition metal cluster compound according to any of [1] to [6], the method including reacting a solution containing the transition metal compound with a carboxylic acid having a structure represented by General Formula (1) or General Formula (2).

[8] The method for producing the transition metal cluster compound according to [7], wherein the solution containing a transition metal compound is a transition metal alkoxide solution.

[9] The method for producing the transition metal cluster compound according to [7], wherein the solution containing a transition metal compound is a transition metal chloride solution.

[10] A photosensitive composition containing the transition metal cluster compound according to any of [1] to [6].

[11] The photosensitive composition according to [10], wherein the photosensitive composition reacts by light having a wavelength of from 6 nm to 15 nm.

[12] A pattern forming method including applying the photosensitive composition according to [10] or [11] onto a substrate, exposing with actinic radiation, and developing the photosensitive composition.

[13] A pattern forming method including applying the photosensitive composition according to [10] or [11] onto a substrate, exposing with actinic radiation, and developing the photosensitive composition with a developer.

[14] The pattern forming method according to [13], wherein the developer is an organic solvent having a solubility parameter (SP value) of 7.5 to 11.

[15] A substrate having a patterned layer obtained by the pattern forming method according to any of [12] to [14].

[16] A method for producing a substrate having a patterned layer obtained by the pattern forming method according to any of to [14].

### Advantageous Effects of Invention

The transition metal cluster compound of the present invention contains two or more types of carboxy ligands and exhibits effects such as excellent storage stability and developability, and the effects are presumed to be exhibited by the following mechanism.

One type of the carboxy ligands is a carboxy ligand including an alicyclic structure having a double bond. It is considered that the double bond reacts by electron beam (EB) irradiation or extreme ultraviolet light (EUV light) exposure, rendering the compound insoluble in an organic solvent, and thereby forming a negative pattern and resulting in excellent developability. It is also considered that another carboxy ligand improves the hydrophobicity of the cluster compound or controls the crystallinity, whereby the transition metal cluster compound is less likely to be affected by oxygen or moisture, and thus exhibits excellent storage stability.

### Description of Embodiments

Hereinafter, the present invention will be described on the basis of one embodiment. However, the present invention is not limited to this embodiment.

In the present specification, some explanations use the term “to” as a descriptive expression representing a numerical range from a lower limit numerical value to an upper limit numerical value. The numerical ranges in these explanations are numerical ranges that are specified as ranges from equal to or greater than the lower limit value to equal to or less than the upper limit value, with the ranges being inclusive of both the lower limit value itself and the upper limit value itself.

### Transition Metal Cluster Compound

A transition metal cluster compound according to one embodiment of the present invention (hereinafter also referred to as the present cluster compound) comprises 2 or more and 20 or less transition metal atoms and two or more types of carboxy ligands, wherein at least one type of the carboxy ligands comprises an alicyclic structure having a double bond. In the present invention, the term “cluster compound” means a metal complex molecule which has a plurality of metal atoms and a ligand and in which the metal atoms are bonded to one another directly or via a bridging ligand. The present cluster compound may contain oxygen and/or a hydroxyl group in the structure. Preferably, the compound may contain a μ-oxo ligand (μ-O) and/or a μ-hydroxy ligand (μ-OH).

The transition metal atoms of the present cluster compound are preferably one or more selected from zirconium, hafnium, and titanium, and among these, zirconium or hafnium is preferable. Hafnium is an element of the same group as zirconium and has chemical and physical properties that are very similar to those of zirconium.

The number of transition metal atoms in the present cluster compound is preferably 2 or more and 20 or less, more preferably 4 or more and 20 or less, and particularly preferably 6 or more and 12 or less.

The present cluster compound is formed of two or more types of carboxy ligands, at least one type of which comprises an alicyclic structure having a double bond, and the carbon adjacent to the carbonyl carbon of the carboxy ligand is a secondary or tertiary carbon. The carboxy ligand including an alicyclic structure having a double bond is preferably one having a cycloalkenyl group, and for example, a ligand represented by the following General Formula (1) or (2) is preferable.

At least one type of the two or more types of carboxy ligands is preferably a carboxy ligand not including an alicyclic structure having a double bond, and furthermore, a carboxy ligand other than the carboxy ligand having a structure represented by the following General Formula (1) or (2) is preferably used.

The two or more types of carboxy ligands more preferably include a ligand represented by the following General Formula (1) or (2) and a carboxy ligand having a saturated hydrocarbon group, and particularly preferably include a ligand represented by General Formula (1) or (2) and a carboxy ligand having a branched saturated hydrocarbon group.

The structures of the ligands can be analyzed by a known method such as NMR, for example. The proportions of the two or more types of carboxy ligands that are introduced can also be analyzed by NMR.

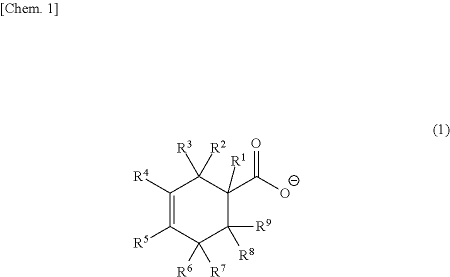

(In Formula (1), R¹ represents hydrogen, a halogen, a heteroatom-containing group, or a hydrocarbon group, and R² to R⁹ each independently represent hydrogen, a halogen, a heteroatom-containing group, or an organic group.)

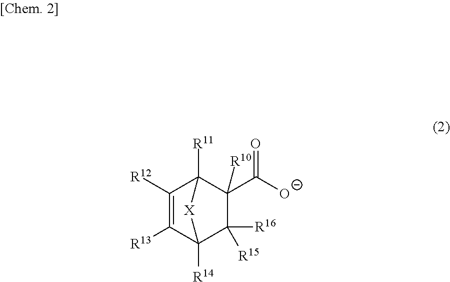

(In Formula (2), R¹⁰ represents hydrogen, a halogen, a heteroatom-containing group, or a hydrocarbon group, and R¹¹ to R¹⁶ each independently represent hydrogen, a halogen, a heteroatom-containing group, or an organic group. X represents oxygen or an alkyl bridge.)

In General Formulae (1) and (2), R¹ and R¹⁰ represent (i) hydrogen, (ii) a halogen, (iii) a heteroatom-containing group, or (iv) a hydrocarbon group, and R² to R⁹ and R¹¹ to R¹⁶ each independently represent (i) hydrogen, (ii) a halogen, (iii) a heteroatom-containing group, or (iv) an organic group.

Examples of the halogen (ii) include a fluorine atom, a chlorine atom, a bromine atom, and an iodine atom.

Examples of the heteroatom in the heteroatom-containing group (iii) include oxygen, nitrogen, phosphorus, sulfur, and silicon.

The heteroatom-containing group (iii) may be a group formed of a heteroatom or a group containing a heteroatom.

Specific examples of the heteroatom-containing group include OR¹⁷, CO₂R¹⁷, C(O)N(R¹⁷)₂, C(O)R¹⁷, SR¹⁷, SO₂R¹⁷, SOR¹⁷, OSO₂R¹⁷, P(O)(OR¹⁷)_{2-y}(R¹⁸)_{y}, CN, NHR¹⁷, N(R¹⁷)₂, Si(OR¹⁸)₃₋ₓ(R¹⁸)ₓ, OSi(OR¹⁸)₃₋ₓ(R¹⁸)ₓ, NO₂, and an epoxy-containing group.

Here, R¹⁷ is hydrogen or a hydrocarbon group having from 1 to 20 carbons. R¹⁸ is a hydrocarbon group having from 1 to 20 carbons. In addition, x is an integer of from 0 to 3, and y is an integer of from 0 to 2.

Specific examples of the heteroatom-containing group (iii) include a methoxy group, an ethoxy group, a phenoxy group, a nitrile group, a trimethylsilyl group, a triethylsilyl group, a dimethylphenylsilyl group, a trimethoxysilyl group, a triethoxysilyl group, a trimethylsilyloxy group, a trimethoxysiloxy group, and a cyclohexylamino group.

The organic group (iv) is preferably a hydrocarbon group, and examples thereof include linear alkyl groups such as a methyl group and an ethyl group; branched alkyl groups such as an isopropyl group and a butyl group; cycloalkyl groups that may have a side chain; aryl groups such as a phenyl group; arylalkyl groups; and alkylaryl groups. Other suitable examples include hydrocarbon groups in which hydrogen is substituted with a halogen element, such as a trifluoromethyl group. The total number of carbons in such organic groups and hydrocarbon groups is preferably from 1 to 30, more preferably from 1 to 20, and still more preferably from 1 to 15.

The organic group (iv) may have a heteroatom, and the organic group (iv) may be substituted with a group formed of a heteroatom and/or a group containing a heteroatom, such as those indicated in (iii).

In the organic group that may have a heteroatom, the total number of carbons of each substituent is preferably from 1 to 30, more preferably from 1 to 20, and still more preferably from 1 to 15.

The organic group (iv) may have a heteroatom, but (iii) and (iv) are not the same.

In General Formula (2), X is an oxygen bridge or an alkyl bridge such as methylene or ethylene.

Examples of the carboxy ligand not including an alicyclic structure having a double bond include a carboxy ligand having a linear saturated hydrocarbon group, and a carboxy ligand having a branched saturated hydrocarbon group. From the viewpoint of controlling the amorphous property of the present cluster compound, the number of carbons in these ligands is preferably from 1 to 30, more preferably from 2 to 20, and particularly preferably from 3 to 10. Among these, a carboxy ligand having a branched saturated hydrocarbon group is preferred from the viewpoint described above.

Examples of the carboxy ligand having a branched saturated hydrocarbon group include conjugate bases of isobutyric acid, pivalic acid, 2-methylbutanoic acid, 2-methylpentanoic acid, 2-methylhexanoic acid, 2-methylheptanoic acid, 2,2-dimethylbutanoic acid, 2-ethylbutanoic acid, 2-ethylpentanoic acid, 2-ethylhexanoic acid, 2-ethylheptanoic acid, 3-methylbutanoic acid, 3-methylpentanoic acid, 3,3-dimethylbutanoic acid, 2-hexyloctanoic acid, cyclopropanecarboxylic acid, cyclobutanecarboxylic acid, cyclopentanecarboxylic acid, and cyclohexanecarboxylic acid.

In a case in which at least one type of the two or more types of carboxy ligands is a carboxy ligand including an alicyclic structure having a double bond and at least one type of the two or more types of carboxy ligands is a carboxy ligand not including an alicyclic structure having a double bond, the ratio of the amounts of these substances as a value of (the carboxy ligand including an alicyclic structure having a double bond):(the carboxy ligand not including an alicyclic structure having a double bond) is preferably from 99:1 to 50:50 and more preferably from 95:5 to 70:30.

In a case in which the two or more types of carboxy ligands are configured to include the ligand represented by General Formula (1) or (2) and the carboxy ligand having a branched saturated hydrocarbon group, the ratio of the amounts of these substances as a value of (the ligand represented by General Formula (1) or (2)):(the carboxy ligand having a branched saturated hydrocarbon group) is preferably from 99:1 to 50:50, and more preferably from 95:5 to 70:30.

The molecular weight of the present cluster compound is preferably from 1000 to 8000, more preferably from 1000 to 6000, and still more preferably from 1500 to 5000.

When the molecular weight of the present cluster compound is equal to or less than the above upper limit, the volume thereof is also small, and therefore it is expected that the roughness and the resolution will be high, whereas when the molecular weight is equal to or more than the above lower limit, the coating film properties and etching resistance tend to improve. This molecular weight is a guideline, and the lithography properties are not determined by the molecular weight alone, and therefore, the molecular weight is not limited thereto.

### Production Method

The present cluster compound can be produced by, for example, reacting two or more types of carboxylic acids with a solution containing a transition metal compound.

At least one type of the two or more types of carboxylic acids is a carboxylic acid having an alicyclic structure with a double bond.

As the carboxylic acid having an alicyclic structure with a double bond, a carboxylic acid having a structure represented by General Formula (1) or General Formula (2) can be used.

At least one type of the two or more types of carboxylic acids is preferably a carboxylic acid not including an alicyclic structure having a double bond. Such a carboxylic acid is more preferably, for example, a carboxylic acid having a linear saturated hydrocarbon group or a carboxylic acid having a branched saturated hydrocarbon group. From the viewpoint of controlling the amorphous property of the cluster compound, the number of carbons of these carboxylic acids is preferably from 1 to 30, and more preferably from 1 to 20.

Among these, a carboxylic acid having a branched saturated hydrocarbon group is preferable from the viewpoint described above.

In one embodiment of the present invention, the present cluster compound can be produced by reacting a solution containing a transition metal compound with a carboxylic acid including an alicyclic structure having a double bond and a carboxylic acid not including an alicyclic structure having a double bond.

In one embodiment of the present invention, the present cluster compound can be produced by reacting a solution containing a transition metal compound with a carboxylic acid having a structure represented by General Formula (1) or General Formula (2) and a carboxylic acid having a branched saturated hydrocarbon group.

Examples of the carboxylic acid having a ligand structure represented by General Formula (1) include carboxylic acids having structures described below. Specific examples thereof include 3-cyclohexene-1-carboxylic acid.

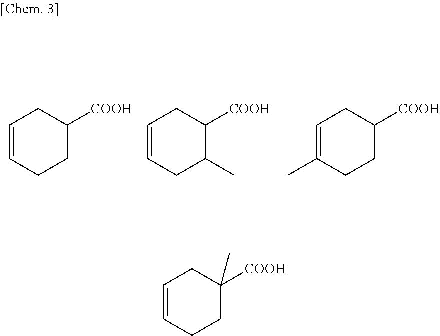

Examples of the carboxylic acid having a ligand structure represented by General Formula (2) include carboxylic acids having structures described below. Specific examples thereof include 5-norbornene-2-carboxylic acid.

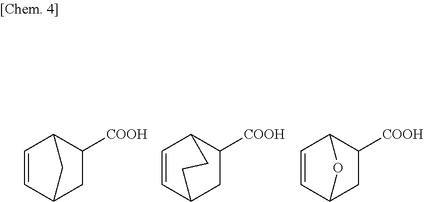

Examples of the carboxylic acid having a branched saturated hydrocarbon group include isobutyric acid, pivalic acid, 2-methylbutanoic acid, 2-methylpentanoic acid, 2-methylhexanoic acid, 2-methylheptanoic acid, 2,2-dimethylbutanoic acid, 2-ethylbutanoic acid, 2-ethylpentanoic acid, 2-ethylhexanoic acid, 2-ethylheptanoic acid, 3-methylbutanoic acid, 3-methylpentanoic acid, 3,3-dimethylbutanoic acid, 2-hexyloctanoic acid, cyclopropanecarboxylic acid, cyclobutanecarboxylic acid, cyclopentanecarboxylic acid, and cyclohexanecarboxylic acid.

Specific examples thereof include 2-ethylhexanoic acid and pivalic acid.

More specifically, a solution containing a transition metal compound and two or more types of carboxylic acids are placed in a reaction vessel and stirred. A solvent may be added to dissolve the raw materials. From the viewpoint of completing the reaction and not causing an undesirable side reaction, the reaction temperature is preferably from room temperature to 150° C., and more preferably from room temperature to 100° C. The reaction time is preferably from 1 to 100 hours, and more preferably from 3 to 24 hours.

When the product precipitates or is deposited in crystal form after the reaction, the product is filtered to produce the present cluster compound. In order to obtain a precipitate or crystals of the product, the solution after the reaction may be cooled to a temperature from −30° C. to 20° C.

When precipitation of the product is not confirmed after the reaction, the reaction solution is brought into contact with a poor solvent to reprecipitate the product.

The reaction vessel is desirably a sealed vessel. When a small amount of reactant is used, for example, a Schlenk tube or the like can be used. The reaction is preferably carried out under a nitrogen or argon atmosphere.

The reaction vessel is preferably a flask equipped with a reflux condenser, and when heating is to be carried out, the reaction is preferably carried out under a nitrogen or argon atmosphere.

Examples of the solution containing a transition metal compound include a solution containing a transition metal alkoxide compound and a solution containing a transition metal chloride compound.

Examples of the transition metal alkoxide compound include zirconium methoxide, zirconium ethoxide, zirconium n-propoxide, zirconium isopropoxide, zirconium n-butoxide, zirconium t-butoxide, and zirconium 2-ethylhexoxide.

Examples of the transition metal chloride compound include zirconium chloride, zirconium oxychloride, and hydrates thereof.

The solution containing a transition metal compound and the two or more types of carboxylic acids are blended at a substance amount ratio of preferably from 1:2 to 1:20, and more preferably from 1:3 to 1:10.

### Photosensitive Composition

A photosensitive composition according to one embodiment of the present invention (hereinafter also referred to as the present photosensitive composition) contains the present cluster compound. The present photosensitive composition may contain only one type of the present cluster compound, or may contain two or more types thereof. Moreover, the present photosensitive composition may contain two or more types of the present cluster.

The content of the present cluster compound in the present photosensitive composition is usually from 30 to 100 mass %, preferably from 40 to 100 mass %, and particularly preferably from 50 to 100 mass % relative to the total amount of the components of the photosensitive composition other than the solvent.

When the content of the present cluster compound in the present photosensitive composition is equal to or more than the above lower limit, good exposure sensitivity can be achieved.

### Photoacid Generator

The present photosensitive composition can be caused to function by containing, together with the present cluster compound, a photoacid generator that generates an acid through the action of actinic radiation.

Examples of the actinic radiation include the emission line spectrum of a mercury lamp, far-ultraviolet light typified by excimer laser, extreme ultraviolet light (EUV light), X-rays, and electron beams. From the viewpoint of resolution, the exposure wavelength is preferably small, and thus extreme ultraviolet light (EUV light) that emits light having a wavelength of from 6 nm to 15 nm is preferred.

Such a photoacid generator that generates an acid with actinic radiation is not particularly limited as long as the photoacid generator is a known photoacid generator, and the photoacid generator is preferably a compound that generates at least any of an organic acid such as sulfonic acid, bis(alkylsulfonyl)imide, and tris(alkylsulfonyl)methide in response to irradiation with actinic radiation.

A single type of photoacid generator may be used alone, or two or more types thereof may be used in combination. In a case in which two or more types of photoacid generators are used in combination, preferable aspects include, for example, (1) a case in which two types of photoacid generators having different acid strengths are used in combination, and (2) a case in which two types of photoacid generators for which the generated acids differ in size (molecular weight or number of carbons) are used in combination.

Examples of the aspect (1) include the combined use of a fluorine-containing sulfonic acid generator and a tris(fluoroalkylsulfonyl) methide acid generator, the combined use of a fluorine-containing sulfonic acid generator and a sulfonic acid generator not containing fluorine, and the combined use of an alkylsulfonic acid generator and an arylsulfonic acid generator.

Examples of the aspect (2) include the combined use of two types of acid generators for which the number of carbons of the generated acid anions differs by 4 or more.

In particular, the present photosensitive composition is preferably a photosensitive composition used for actinic radiation. A photosensitive composition that reacts by actinic radiation is preferable because the development rate with respect to the developer changes, and thus a pattern can be formed after development for a certain period of time.

As the actinic radiation, light having a shorter wavelength is preferable because higher resolution can be obtained. Light having a wavelength of from 6 nm to 15 nm is preferred, and light having a wavelength from 6.5 nm to 13.5 nm is more preferred. That is, extreme ultraviolet light (EUV light) is preferable.

In other words, the present photosensitive composition is preferably a photosensitive composition that reacts by light having a wavelength of from 6 nm to 15 nm.

The present photosensitive compound is photosensitive and reacts by light even when used alone in the photosensitive composition. In a case in which a photoacid generator is added, the photoacid generator acts synergistically with the present cluster compound in the photosensitive composition, and therefore, the photosensitivity of the present cluster compound can be enhanced. Thus, a photoacid generator is preferably added in a case in which the photosensitivity is insufficient with regard to the required specification of a photosensitive composition formed only from the present cluster compound.

In a case in which the present photosensitive composition contains a photoacid generator, the content of the photoacid generator (the total amount in a case in which a plurality of photoacid generators are used in combination) in the present photosensitive composition is preferably from 0.1 to 30 mass %, more preferably from 0.5 to 20 mass %, and still more preferably from 1 to 15 mass %, based on the total amount of the components of the photosensitive composition other than the solvent.

When the content of the photoacid generator in the photosensitive composition is equal to or more than the above lower limit, an effect of enhancing photosensitivity is achieved, whereas when the content is equal to or less than the above upper limit, the photosensitive composition is not easily affected by the poor film formability of the photoacid generator, and therefore good film formability based on the photosensitive compound of the present invention is achieved. Thus, such a content is preferable.

### Solvent

The present photosensitive composition usually contains a solvent for preparing a liquid.

The solvent for preparing a liquid of the photosensitive composition is not particularly limited as long as it dissolves each component, and examples of the solvent include toluene, alkylene glycol monoalkyl ether carboxylates (propylene glycol monomethyl ether acetate (PGMEA; 1-methoxy-2-acetoxypropane), and the like), alkylene glycol monoalkyl ethers (propylene glycol monomethyl ether (PGME; 1-methoxy-2-propanol), and the like), alkyl lactates (ethyl lactate, methyl lactate, and the like), cyclic lactones (γ-butyrolactone and the like, preferably having from 4 to 10 carbons), chain or cyclic ketones (2-heptanone, cyclohexanone, and the like, preferably having from 4 to 10 carbons), alkylene carbonates (ethylene carbonate, propylene carbonate, and the like), alkyl carboxylates (alkyl acetates such as butyl acetate are preferable), alkyl alkoxyacetates (ethyl ethoxypropionate), alkylamides (N,N-dimethylformamide), and alkyl sulfoxides (dimethyl sulfoxide). Examples of other usable solvents include the solvents described in paragraph and subsequent paragraphs of the specification of US 2008/0248425 A1.

Among the above, toluene, PGMEA, ethyl lactate, cyclohexanone, 2-heptanone, N,N-dimethylformamide, dimethyl sulfoxide, alkylene glycol monoalkyl ether carboxylates, and alkylene glycol monoalkyl ethers are preferable.

A single type of these solvents may be used alone, or two or more types thereof may be mixed and used. In a case in which two or more types of solvents are mixed, it is preferable to mix a solvent having a hydroxyl group and a solvent not having a hydroxyl group.

The solvent having a hydroxyl group is preferably an alkylene glycol monoalkyl ether, and the solvent not having a hydroxyl group is preferably an alkylene glycol monoalkyl ether carboxylate, N,N-dimethylformamide, or dimethyl sulfoxide.

The content of the solvent in the total amount of the present photosensitive composition can be appropriately adjusted depending on details such as the film thickness of the pattern to be formed, and the content thereof is generally adjusted so that the total concentration of the components of the photosensitive composition other than the solvent is from 0.5 to 30 mass %, preferably from 1.0 to 20 mass %, more preferably from 1.5 to 10 mass %, and still more preferably from 1.5 to 5 mass %.

### Surfactant

The present photosensitive composition preferably further contains a surfactant. The surfactant is preferably a fluorine-based and/or silicon-based surfactant.

Examples of surfactants corresponding to these include Megaface F176 and Megaface R08 available from DIC Corporation, PF656 and PF6320 available from OMNOVA Solutions Inc., Troysol S-366 available from Troy Corporation, Fluorad FC430 available from Sumitomo 3M Ltd., and Polysiloxane Polymer KP-341 available from Shin-Etsu Chemical Co., Ltd.

A surfactant other than a fluorine-based and/or silicon-based surfactant may also be used. More specifically, examples include polyoxyethylene alkyl ethers and polyoxyethylene alkyl aryl ethers.

Other known surfactants can be used, as appropriate. Examples of usable surfactants include the surfactants described in paragraph and subsequent paragraphs of the specification of US 2008/0248425 A1.

A single type of these surfactants may be used alone, or two or more types thereof may be used in combination.

The content of the surfactant is preferably from 0.0001 to 2 mass %, and more preferably from 0.001 to 1 mass %, relative to the total amount of the components of the photosensitive composition other than the solvent.

### Resin

The present photosensitive composition can form a pattern alone, but may contain a resin material in addition to the present cluster compound. The resin material is not particularly limited as long as it is dissolved in the solvent, and examples of the resin material include a novolac resin, a styrene resin, and an acrylic resin. These resin materials may be used alone or in combination of two or more types thereof, may contain, in the molecular structure thereof, a dissolution-inhibiting group that is decomposed by a chemically active species such as an acid or a radical, or a crosslinkable group that is crosslinked by a chemically active species such as an acid or a radical, or the like, and may be a copolymer resin of two or more types of the resin materials. Examples of the dissolution-inhibiting group that is decomposed by a chemically active species such as an acid or a radical include an alkoxycarbonyl group and an acetal group. Examples of the crosslinkable group that is crosslinked by a chemically active species such as an acid or a radical include a vinyl group, a carbodiimide group, an N-hydroxyester group, an imidoester group, a maleimide group, a haloacetyl group, a pyridyl disulfide group, a hydrazide group, an alkoxyamino group, and a diazirine group.

### Additional Additive

As appropriate, the present photosensitive composition may contain, in addition to the components described above, an additional additive such as a carboxylic acid, a carboxylic acid onium salt, a dissolution-inhibiting compound having a molecular weight of 3000 or less as described in, for example, Proceeding of SPIE, 2724, 355 (1996), a dye, a plasticizer, a photosensitizer, a light absorber, a crosslinking agent, or an antioxidant.

In particular, a carboxylic acid is particularly suitable for use in improving performance. The carboxylic acid is preferably an aromatic carboxylic acid such as benzoic acid or naphthoic acid.

The content of the carboxylic acid is preferably from 0.01 to 10 mass %, more preferably from 0.01 to 5 mass %, and still more preferably from 0.01 to 3 mass % relative to the total amount of the components of the photosensitive composition other than the solvent.

### Method for Producing Present Photosensitive Composition

The present photosensitive composition can be produced by dissolving the present cluster compound and optionally a photoacid generator and additional components in a solvent for preparing a liquid, and filtering the solution through a filter as necessary. The filter is preferably made of polytetrafluoroethylene, polyethylene, or nylon and has a pore size of 0.2 μm or less, more preferably 0.1 μm or less, and even more preferably 0.05 μm or less.

### Pattern Forming Method

The pattern forming method according to one embodiment of the present invention (hereinafter also referred to as the present pattern forming method) includes a step of applying the present photosensitive composition onto a substrate, a step of exposing with actinic radiation, and a step of developing the photosensitive composition.

More specifically, the method includes a step of applying the present photosensitive composition onto a substrate to form a photosensitive layer, a step of irradiating a predetermined area of the photosensitive layer with actinic radiation to carry out pattern exposure, and a step of developing the exposed photosensitive layer with a developer to selectively remove an exposed portion or an unexposed portion of the photosensitive layer.

### Photosensitive Layer Forming Step

The photosensitive layer can be formed by applying, through an appropriate application method such as a spinner, the present photosensitive composition onto a substrate (e.g., silicon substrate, or silicon dioxide-coated substrate) such as one that is used in the production of an integrated circuit element, and then drying the composition at a temperature of from 50 to 150° C.

At this time, a commercially available inorganic or organic antireflection film can be used as necessary. Further, an antireflection film may be applied to a resist underlayer and used.

### Exposure Step

In the present invention, unless otherwise specified, the term “exposure” includes not only exposure by a mercury lamp, far-ultraviolet light typified by excimer lasers, X-rays, extreme ultraviolet light (EUV light), and the like, but also exposure by drawing with a particle beam such as an electron beam or an ion beam.

The exposure can be carried out by irradiating a predetermined area of the formed photosensitive layer with actinic radiation through a predetermined mask to perform pattern exposure, or by irradiating the photosensitive layer with an electron beam to carry out pattern exposure by drawing (direct writing) without using a mask.

The actinic radiation is not particularly limited, and examples thereof include a KrF excimer laser, an ArF excimer laser, extreme ultraviolet light (EUV light), and an electron beam. Of these, extreme ultraviolet light (EUV light) and an electron beam are preferable, and as described above, extreme ultraviolet light (EUV light) that emits light having a wavelength of from 6 nm to 15 nm is preferable.

After the exposure, baking (heating) may or may not be implemented before development.

The heating temperature when baking (heating) is to be carried out is preferably from 50 to 150° C., more preferably from 60 to 150° C., and still more preferably from 80 to 140° C.

The heating time when baking (heating) is to be carried out is preferably from 30 to 300 seconds, more preferably from 30 to 180 seconds, and still more preferably from 30 to 90 seconds.

The heating can be carried out by a means provided in a usual exposure and development machine, and may be carried out using a hot plate or the like.

### Development Step

After the exposure, development is carried out to selectively remove an exposed or unexposed portion of the photosensitive layer. Any known development method can be employed, and for example, a method using a gas or a method using a developer may be used.

### Developer

As the developer, an organic solvent is preferably used, and an organic solvent having a vapor pressure at 20° C. of 5 kPa or less is preferred, an organic solvent having a vapor pressure at 20° C. of 3 kPa or less is more preferred, and an organic solvent having a vapor pressure at 20° C. of 2 kPa or less is particularly preferred. By keeping the vapor pressure of the organic solvent at 5 kPa or less, evaporation of the developer on the substrate or in the developing cup is suppressed, and temperature uniformity in the patterned substrate surface is improved, and as a result, dimensional uniformity in the patterned substrate surface is also improved.

Various organic solvents can be used as the developer. For example, at least one type of solvent selected from solvents such as ester-based solvents, ketone-based solvents, alcohol-based solvents, amide-based solvents, sulfoxide-based solvents, ether-based solvents, and hydrocarbon-based solvents can be used.

Examples of the ester-based solvents include alkyl carboxylate-based solvents such as methyl acetate, butyl acetate, ethyl acetate, isopropyl acetate, amyl acetate, ethyl-3-ethoxypropionate, propylene glycol diacetate, 3-methoxybutyl acetate, 3-methyl-3-methoxybutyl acetate, methyl formate, ethyl formate, butyl formate, propyl formate, ethyl lactate, butyl lactate, and propyl lactate; and alkylene glycol monoalkyl ether carboxylate-based solvents such as propylene glycol monomethyl ether acetate (PGMEA; also known as 1-methoxy-2-acetoxypropane), ethylene glycol monoethyl ether acetate, diethylene glycol monobutyl ether acetate, diethylene glycol monoethyl ether acetate, and propylene glycol monoethyl ether acetate. More preferred are butyl acetate, amyl acetate, ethyl lactate, and propylene glycol monomethyl ether acetate.

Examples of the ketone-based solvents include 1-octanone, 2-octanone, 1-nonanone, 2-nonanone, acetone, 4-heptanone, 1-hexanone, 2-hexanone, diisobutyl ketone, cyclopentanone, cyclohexanone, methylcyclohexanone, phenylacetone, methyl ethyl ketone, methyl amyl ketone, methyl isobutyl ketone, acetylacetone, acetonylacetone, ionone, diacetonyl alcohol, acetyl carbinol, acetophenone, methyl naphthyl ketone, isophorone, and propylene carbonate. More preferred are alkyl ketone-based solvents such as methyl isobutyl ketone, methyl amyl ketone, cyclopentanone, cyclohexanone, and 2-heptanone.

Examples of the alcohol-based solvents include alcohols such as methyl alcohol, ethyl alcohol, n-propyl alcohol including 1-propanol or 2-propanol, isopropyl alcohol, n-butyl alcohol, sec-butyl alcohol, tert-butyl alcohol, isobutyl alcohol, hexyl alcohols such as n-hexyl alcohol, heptyl alcohols such as n-heptyl alcohol, octyl alcohols such as n-octyl alcohol, and decanols such as n-decanol; glycol-based solvents such as ethylene glycol, diethylene glycol, triethylene glycol, 1,2-propylene glycol, 1,3-propylene glycol, 1,2-butylene glycol, 1,3-butylene glycol, and 1,4-butylene glycol; alkylene glycol monoalkyl ether-based solvents such as ethylene glycol monomethyl ether, propylene glycol monomethyl ether (PGME; also known as 1-methoxy-2-propanol), ethylene glycol monoethyl ether, propylene glycol monoethyl ether, diethylene glycol monomethyl ether, and triethylene glycol monoethyl ether; glycol ether-based solvents such as methoxymethyl butanol and propylene glycol dimethyl ether; and phenol-based solvents such as phenol and cresol. More preferred are 1-hexanol, 2-hexanol, 1-octanol, 2-ethyl-hexanol, propylene glycol monomethyl ether, and cresol.

Examples of amide-based solvents that can be used include N-methyl-2-pyrrolidone, N,N-dimethylacetamide, N,N-dimethylformamide, hexamethylphosphoric triamide, and 1,3-dimethyl-2-imidazolidinone.

Examples of sulfoxide-based solvents that can be used include dimethyl sulfoxide.

Examples of the ether-based solvents include the alkylene glycol monoalkyl ether-based solvents and glycol ether-based solvents described above, as well as dioxane, tetrahydrofuran, and tetrahydropyran.

Examples of the hydrocarbon-based solvents include aromatic hydrocarbon-based solvents such as toluene and xylene, and aliphatic hydrocarbon-based solvents such as pentane, hexane, octane, decane, and dodecane.

The developer preferably contains one or more solvents selected from alkylene glycol monoalkyl ether carboxylate-based solvents, alkylene glycol monoalkyl ether-based solvents, alkyl carboxylate-based solvents, and alkyl ketone-based solvents, and more preferably contains one or more solvents selected from dimethylformamide, dimethyl sulfoxide, tetrahydrofuran, ethylene glycol, methyl alcohol, ethyl alcohol, 1-propanol, and 2-propanol.

The developer to be used is preferably a developer containing at least one organic solvent selected from the group consisting of an ester-based solvent having no hydroxyl group in the molecule, a ketone-based solvent having no hydroxyl group in the molecule, an ether-based solvent having no hydroxyl group in the molecule, an amide-based solvent, and a sulfoxide-based solvent.

The organic solvent used as the developer in the present invention is preferably an organic solvent having a solubility parameter (SP value) of 7.5 to 11. An organic solvent having a solubility parameter of 7.5 or more is preferred because the development rate of a dissolved portion is increased, and an organic solvent having a solubility parameter of 11 or less is preferred because the development rate of a pattern forming portion can be suppressed. The solubility parameter of the organic solvent as the developer is more preferably 8 to 11.

In the present invention, the value of the solubility parameter (SP value) is calculated by the method proposed by Fedors and others. Specifically, the SP value is a value determined with reference to “POLYMER ENGINEERING AND SCIENCE, February 1974, Vol. 14, No. 2, Robert F. FEDORS (pp. 147-154)”. The SP value is a physical property value that is determined by the content of a hydrophobic group or a hydrophilic group in the molecule, and when a mixed solvent is used, the SP value means the value of the mixture.

Examples of the organic solvent satisfying the above SP value include diethylene glycol monomethyl ether (SP value=10.7), triethylene glycol monomethyl ether (SP value=10.7), ethylene glycol monoisopropyl ether (SP value=10.9), ethylene glycol monobutyl ether (SP value=10.2), diethylene glycol monobutyl ether (SP value=10.0), triethylene glycol monobutyl ether (SP value=10.0), ethylene glycol monoisobutyl ether (SP value=9.1), ethylene glycol monohexyl ether (SP value=9.9), diethylene glycol monohexyl ether (SP value=9.7), diethylene glycol mono2-ethylhexyl ether (SP value=9.3), ethylene glycol monoallyl ether (SP value=10.8), ethylene glycol monophenyl ether (SP value=10.8), ethylene glycol monobenzyl ether (SP value=10.9), propylene glycol monomethyl ether (SP value=10.0), dipropylene glycol monomethyl ether (SP value=9.7), tripropylene glycol monomethyl ether (SP value=9.4), propylene glycol monopropyl ether (SP value=9.6), dipropylene glycol monopropyl ether (SP value=9.8), propylene glycol monobutyl ether (SP value=9.0), dipropylene glycol monobutyl ether (SP value=9.6), ethylene glycol monomethyl ether acetate (SP value=10.0), ethylene glycol monoethyl ether acetate (SP value=9.6), ethylene glycol monobutyl ether acetate (SP value=8.9), diethylene glycol monoethyl ether acetate (SP value=9.4), diethylene glycol monobutyl ether acetate (SP value=9.0), propylene glycol monomethyl ether acetate (SP value=9.4), propylene glycol monoethyl ether acetate (SP value=9.0), or dipropylene glycol monomethyl ether acetate (SP value=9.2).

A plurality of the organic solvents described above may be mixed and used, or the organic solvent may be mixed and used with water or a solvent other than the solvents described above.

The concentration of the organic solvent (total in the case of mixing a plurality of organic solvents) in the developer is preferably 50 mass % or more, more preferably 70 mass % or more, and still more preferably 90 mass % or more. Particularly preferred is a developer that is substantially composed of only an organic solvent. A case in which the developer is substantially composed of only an organic solvent includes a case in which the developer contains a trace amount of a surfactant, an antioxidant, a stabilizer, an antifoaming agent, or the like.

The water content of the developer is preferably 10 mass % or less, more preferably 5 mass % or less, and particularly preferably 3 mass % or less, and most preferably, the developer is substantially free of water. When the water content is 10 mass % or less, good development properties can be achieved.

As necessary, an appropriate amount of a surfactant may be added to the developer used in the present invention.

As the surfactant, the same surfactant as described above as the surfactant used in the photosensitive composition of the present invention can be used.

The amount of the surfactant used is usually from 0.001 to 5 mass %, preferably from 0.005 to 2 mass %, and more preferably from 0.01 to 0.5 mass % relative to the total amount of the developer.

### Development Method

Examples of the development method include a method of immersing the substrate for a certain period of time in a tank filled with the developer (dipping method), a method of developing by accumulating the developer on the substrate surface through surface tension and allowing the developer to stand thereon for a certain period of time (puddle method), a method of spraying the developer onto the substrate surface (spraying method), and a method of scanning a substrate rotating at a constant speed with a developer application nozzle while continuously dispensing the developer onto the substrate (dynamic dispensing method).

After the development step, a step of stopping development while replacing the solvent with another solvent may be carried out.

The development time is preferably the time required to sufficiently dissolve the present cluster compound and the like in the photosensitive layer of the unexposed area or the exposed area, and is usually preferably from 10 to 300 seconds, and more preferably from 20 to 120 seconds.

The temperature of the developer is preferably from 0 to 50° C., and more preferably from 15 to 35° C.

The amount of the developer can be appropriately adjusted according to the development method.

### Rinsing Step

The present pattern forming method may include, after the development step, a step of washing with a rinsing liquid containing an organic solvent.

### Rinsing Liquid

The organic solvent used in the rinsing liquid preferably has a vapor pressure at 20° C. of 0.05 kPa or more and 5 kPa or less, more preferably 0.1 kPa or more and 5 kPa or less, and most preferably 0.12 kPa or more and 3 kPa or less. By setting the vapor pressure of the organic solvent used in the rinsing liquid to 0.05 kPa or more and 5 kPa or less, temperature uniformity in the wafer surface is improved, and furthermore, swelling caused by permeation of the rinsing liquid is suppressed, and dimensional uniformity in the wafer surface is improved.

Various organic solvents may be used as the rinsing liquid, but for the present cluster compound, it is preferable to use a rinsing liquid containing water or at least one organic solvent selected from hydrocarbon-based solvents, ketone-based solvents, ester-based solvents, alcohol-based solvents, amide-based solvents, and ether-based solvents.

More preferably, after the development, a step of washing is carried out using a rinsing liquid containing at least one organic solvent selected from ketone-based solvents, ester-based solvents, alcohol-based solvents, amide-based solvents, and hydrocarbon-based solvents. Still more preferably, after the development, a step of washing is carried out using a rinsing liquid containing at least one or more organic solvents selected from the group consisting of alcohol-based solvents and hydrocarbon-based solvents.

Specific examples of the ketone-based solvents, ester-based solvents, alcohol-based solvents, amide-based solvents, ether-based solvents, and hydrocarbon-based solvents used as the rinsing liquid are the same as those described with regard to the developer described above.

Particularly preferably, a rinsing liquid containing at least one or more organic solvents selected from the group consisting of monohydric alcohol-based solvents, hydrocarbon-based solvents, and amide-based solvents is used.

Examples of the monohydric alcohol-based solvent used in the rinsing step after development include linear, branched, and cyclic monohydric alcohols, and specific examples thereof that can be used include 1-butanol, 2-butanol, 3-methyl-1-butanol, tert-butyl alcohol, isopropyl alcohol, cyclopentanol, and cyclohexanol. Of these, 1-butanol, 2-butanol, 3-methyl-1-butanol, and isopropyl alcohol are preferable.

Examples of the hydrocarbon-based solvent include aromatic hydrocarbon-based solvents such as toluene and xylene, and aliphatic hydrocarbon-based solvents such as octane, decane, and dodecane.

As the amide-based solvent, N,N-dimethylformamide or the like can be used.

A plurality of the above-mentioned components may be mixed, or the above-mentioned components may be mixed and used with an organic solvent other than those described above.

The organic solvent may be mixed with water, but the water content of the rinsing liquid is usually 30 mass % or less, preferably 10 mass % or less, more preferably 5 mass % or less, and particularly preferably 3 mass % or less. Most preferably, the rinsing liquid does not contain water. When the water content is 30 mass % or less, good development characteristics can be achieved.

The rinsing liquid may also be used by adding an appropriate amount of a surfactant.

As the surfactant, the same surfactant as that described above as the surfactant used in the photosensitive composition can be used, and the amount of the surfactant used is usually from 0.001 to 5 mass %, preferably from 0.005 to 2 mass %, and more preferably from 0.01 to 0.5 mass %, relative to the total amount of the rinsing liquid.

### Rinsing Method

In the rinsing step, the developed patterned substrate is subjected to a washing treatment using the rinsing liquid containing an organic solvent.

The method of the washing treatment is not particularly limited, and for example, a method of continuously applying the rinsing liquid onto a substrate rotating at a constant speed (spin coating method), a method of dipping the substrate for a certain period of time in a tank filled with the rinsing liquid (dipping method), or a method of spraying the rinsing liquid onto the substrate surface (spraying method) can be employed. Among these, it is preferable to carry out the washing treatment by the spin coating method and then rotate the washed substrate at a rotational speed of from 2000 to 4000 rpm to remove the rinsing liquid from the substrate. The rotation time of the substrate can be set according to the rotational speed and within a range such that the rinsing liquid is completely removed from the substrate, but is usually from 10 seconds to 3 minutes. Preferably, the rinsing is implemented at room temperature.

The rinsing time is preferably set so that the developing solvent does not remain on the substrate, and is usually preferably from 10 to 300 seconds. The rinsing time is more preferably from 20 to 120 seconds.

The temperature of the rinsing liquid is preferably from 0 to 50° C., and more preferably from 15 to 35° C.

The amount of the rinsing liquid can be appropriately adjusted according to the rinsing method.

### Post-Treatment Step

After the development treatment or the rinsing treatment, a treatment of using a supercritical fluid to remove the developer or rinsing liquid adhered to the pattern can be carried out.

Further, after the development treatment, the rinsing treatment, or the treatment with a supercritical fluid, a heating treatment may be carried out to remove the solvent remaining in the pattern. The heating temperature and time are not particularly limited as long as a good resist pattern is obtained, and are usually from 40 to 160° C. and from 10 seconds to 3 minutes, respectively. The heating treatment may be carried out a plurality of times.

### Applications

The present photosensitive composition and the present pattern forming method are suitably used for the production of semiconductor microcircuits such as the production of VLSI or high-capacity microchips, and can be used to produce a substrate having a patterned layer. In the production of a semiconductor microcircuit, the resist film having a pattern formed thereon is subjected to circuit formation or etching, after which the remaining resist film portion is finally removed with a solvent or the like. Therefore, unlike a so-called permanent resist that is used for a printed circuit board or the like, a resist film derived from the present photosensitive composition does not remain in the final product such as a microchip.

### EXAMPLES

Hereinafter, Examples of the present invention will be described. However, the present invention is not limited to the Examples. In the Examples, the units “parts” and “%” are based on mass unless otherwise specified.

The following compounds 1 to 4 were synthesized for Examples 1 to 3 and Reference Example 1. The composition of each compound and the ligand structure were determined by 1H-NMR. In the following Chemical Formulae 1 to 3, the carboxy ligands are denoted by subscripts of 12/n and 12/m, where n and m represent the proportion of the substance amount of each individual carboxy ligand to the total amount of carboxy ligands in the cluster compound. The proportion of an individual carboxy ligand can be determined by NMR measurement.

The compounds 1 to 4 were analyzed by electrospray ionization mass spectroscopy (ESI-MS), and were confirmed to be cluster compounds.

The ESI-MS measurement was carried out using Xevo G2-XS Qtof available from Waters Corporation.

Each of the compounds 1 to 4 was dissolved in a mixed solvent of THF/acetonitrile, and the solution was filtered through a 0.2 μm filter before use.

A mixed solvent of THF/acetonitrile was used as the mobile phase.

### Compound 1

A zirconium isopropoxide solution (70% propanol solution, 15.0 g, 32.1 mmol) was placed in a flask and diluted with hexane (30 mL). Subsequently, 3-cyclohexene-1-carboxylic acid (14.6 g, 116 mmol) and 2-ethylhexanoic acid (1.85 g, 12.8 mmol) were added. A reflux apparatus was attached to the flask, and the mixture was heated and refluxed in an oil bath at 90° C. for 1 hour. The reaction solution was concentrated with an evaporator to produce a viscous liquid. Methanol (50 mL) was added to the flask, and a waxy solid was generated on the flask wall. The supernatant solution was removed by decantation, and the waxy solid was dried in a vacuum oven (100° C.) for 1 hour, whereby a white powder was obtained. The white powder was washed with methanol (50 mL) and filtered through filter paper. The resultant powder was dried in a vacuum oven (100° C.) for 2 hours, to produce a white powder (5.77 g).

The produced solid was dissolved in CDCl₃ and subjected to NMR analysis. As a result, the solid was found to have a structure represented by Chemical Formula 1. n: 90%, m: 10%

¹H-NMR (CDCl₃, ppm): 0.7-1.0 (br) 1.0-2.6 (br), 5.4-5.8 (br).

ESI-MS (negative): Peak group derived from cluster at m/z of 1750 to 2300

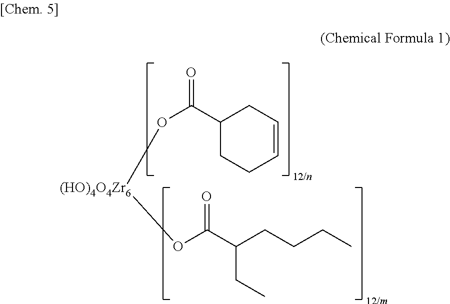

### Compound 2

A zirconium isopropoxide solution (70% propanol solution, 5.15 g, 11.0 mmol) was placed in a flask and diluted with hexane (5 mL). Subsequently, 3-cyclohexene-1-carboxylic acid (5.00 g, 39.6 mmol) and pivalic acid (0.449 g, 4.41 mmol) were added. A reflux apparatus was attached to the flask, and the mixture was heated and refluxed in an oil bath at 90° C. for 1 hour. Methanol (100 mL) was added to the flask, and a white solid was precipitated. The mixture was stirred at room temperature for 1.5 hours, after which the mixture was filtered through filter paper. The resultant powder was dried in a vacuum oven (100° C.) for 2 hours, to produce a white powder (2.18 g).

The produced solid was dissolved in CDCl₃ and subjected to NMR analysis. As a result, the solid was found to have a structure represented by Chemical Formula 2. n: 90%, m: 10%

¹H-NMR (CDCl₃, ppm): 0.9-1.3 (br), 1.3-1.8 (br), 1.8-2.6 (br), 5.4-5.8 (br).

ESI-MS (negative): Peak group derived from cluster at m/z of 1500 to 2500

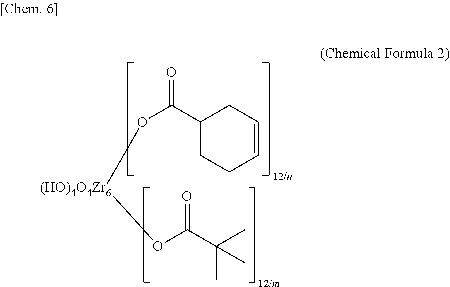

### Compound 3

A zirconium isopropoxide solution (70% propanol solution, 4.61 g, 9.86 mmol) was placed in a flask and diluted with hexane (5 mL). Subsequently, 5-norbornene-2-carboxylic acid (4.90 g, 35.5 mmol) and pivalic acid (0.403 g, 3.94 mmol) were added. A reflux apparatus was attached to the flask, and the mixture was heated and refluxed in an oil bath at 90° C. for 1 hour. Methanol (100 mL) was added to the flask, and a white solid was precipitated. The mixture was stirred at room temperature for 1.5 hours, after which the mixture was filtered through filter paper. The resultant powder was dried in a vacuum oven (100° C.) for 2 hours, to produce a white powder (2.94 g).

The produced solid was dissolved in CDCl₃ and subjected to NMR analysis. As a result, the solid was found to have a structure represented by Chemical Formula 3. n: 90%, m: 10%

¹H-NMR (CDCl₃, ppm): 1.0-1.6 (br), 1.6-2.4 (br), 2.6-3.0 (br), 3.0-3.4 (br), 5.8-6.4 (br).

ESI-MS (negative): Peak group derived from cluster at m/z of 1500 to 2500

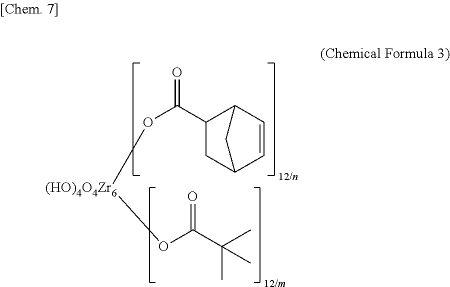

### Compound 4

A zirconium isopropoxide solution (70% propanol solution, 10.0 g, 21.3 mmol) was placed in a flask and diluted with hexane (20 mL). Subsequently, cyclohexene carboxylic acid (10.8 g, 85.4 mmol) was added. A reflux apparatus was attached to the flask, and the mixture was heated and refluxed in an oil bath at 90° C. for 1 hour. Methanol (100 mL) was placed in another flask, and the reaction solution was added dropwise to the methanol. A white suspension was immediately formed, and a white powder was precipitated after stirring for a while. The white powder was filtered and dried in a vacuum oven (100° C.) for 1 hour, to thereby produce 3.59 g of a white powder. The produced solid was subjected to NMR analysis. As a result, the solid was found to have a structure represented by Chemical Formula 4.

n: 90%, m: 10%

¹H-NMR (CDCl₃, ppm): 1.0-2.7 (br, 7H) 5.3-5.8 (br, 2H).

ESI-MS (negative): Peak group derived from cluster at m/z from 1750 to 2200

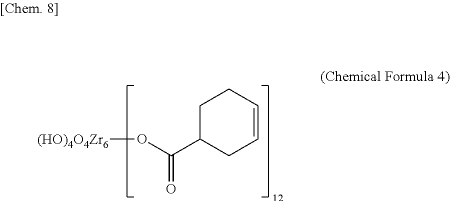

### Cluster Compound Stability Evaluation

A resist liquid can be prepared by dissolving the above-described cluster compound in an organic solvent. The resist liquid is applied onto a substrate such as a silicon wafer using a spin coater, and then subjected to a pre-baking treatment to form a resist film. When the cluster compound is modified and the solubility is changed in these processes, a problem occurs in lithography. Therefore, in order to evaluate the stability of the cluster compound, the cluster compound was dissolved in a solvent, applied onto a silicon wafer, and subjected to a pre-baking treatment, and whether the resultant resist film was dissolved in a developer was ascertained. All of these operations were carried out in the atmosphere.

### Preparation of Photosensitive Composition (Resist Liquid)

Each of the above compounds was dissolved in toluene at a concentration of 3 mass %, and the solution was filtered through a 0.2 μm filter. Thus, resist liquids of Examples 1 to 3 and Reference Example 1 were prepared. The toluene used for the preparation was not of a dehydration grade.

### Pretreatment of Silicon Substrate

A silicon substrate was subjected to a UV-ozone treatment for 20 minutes using a UV ozone cleaner (UV253, available from Filgen Inc.). Subsequently, the substrate was installed on a spin coater (MS-A100, available from Mikasa Co., Ltd.), hexamethyldisiloxane (HMDS) was placed on the substrate surface, and the substrate was rotated at 2000 rpm, to thereby passivate the substrate surface.

### Resist Film Formation

The substrate was installed on a spin coater, hexamethyldisiloxane (HMDS) was placed on the substrate surface and left to stand for 10 seconds, after which the substrate was rotated at 2000 rpm to thereby passivate the substrate surface. Next, the prepared resist liquid was used, and the surface of the silicon substrate was coated with the resist material by spin coating. The silicon substrate was baked at 90° C. for 90 seconds to evaporate the solvent, whereby a substrate sample with a resist film was formed. The thickness of the resist film formed on the substrate was evaluated with an ellipsometer. The results are shown in Table 1.

### Development

As a model experiment of the development step, puddle development using toluene was carried out on the substrate with the resist film.

The substrate with the resist film was installed on a spin coater, and toluene was placed on the surface of the substrate and left to stand for 90 seconds. Next, the substrate was rotated at 2000 rpm to remove the toluene. The residual resist film on the substrate was evaluated using an ellipsometer.

After completion of the above evaluation, the substrate was additionally developed once again by the same operation, and the residual resist film on the substrate was evaluated using an ellipsometer. The results are shown in Table 1.

Film Thickness Measurement with Ellipsometer

The UVISEL spectroscopic ellipsometer (available from HORIBA, Ltd.) was used as a device for measurement. In the measurement using the spectroscopic ellipsometer, a resist film was formed on a silicon substrate that had been subjected to a UV-ozone treatment and an HMDS treatment, the silicon substrate was then placed in the device, and the amount of change in polarization between incident light and reflected light was measured in a wavelength range of 310 nm to 2067 nm. The measurement was performed for three incident angles of 60°, 65°, and 70°. Subsequently, the measurement data for the three incident angles was fitted by the least squares method to a Cauchy dispersion model represented by the following Equation (X), and thereby the film thickness [nm] of the resist film formed on the silicon substrate was calculated.

$$n ( λ ) = A + ( B \cdot {10}^{4} / {λ}^{2} ) + ( C \cdot {10}^{9} / {λ}^{4} ) , k ( λ ) = 0 \qquad Equation ( X )$$

Here, n is refractive index, λ [nm] is wavelength, A, B, and C are constants of 0 or more, and k is the extinction coefficient.

### Results and Discussion

The thicknesses of the resist film on the substrate before and after the development were compared, to thereby calculate the residual film rate of the resist film after development with respect to the resist film thickness before development. The results are shown in Table 1.

TABLE 1

| | | | Resist film | Resist film |
|---|---|---|---|---|
| | | | thickness (nm) | thickness (nm) |
| | | | and residual | and residual |
| | | Initial | film rate (%) | film rate (%) |
| | | resist film | after | after |
| | Resist | thickness | development | development |
| | compound | (nm) | (1st Time) | (2nd Time) |
| Example 1 | Compound 1 | 125 | 1.5 | — |
| | | | 1% | |
| Example 2 | Compound 2 | 125 | 9.7 | 9.7 |
| | | | 8% | 8% |
| Example 3 | Compound 3 | 133 | 4.3 | — |
| | | | 3% | |
| Reference | Compound 4 | 125 | 55.4 | 55.4 |
| Example 1 | | | 44% | 44% |

As shown in Table 1, in the case of the compounds 1 and 3, 97% or more of the resist film was removed, that is, the residual film rate was 3% or less, and it was confirmed that no modification due to baking occurred. Compound 2 was confirmed to be slightly modified by baking, and 8% of the resist film remained. Compound 4 was insolubilized at a considerable rate by baking, and the residual film rate was 44%.

In Examples 1 and 3, the state of the substrate after the first development treatment indicated that development was favorably carried out without the need for the second development treatment, and therefore the second development treatment was not carried out. In Example 2, even when the second development treatment was carried out, the residual film rate was not further decreased from the result of the first development treatment. Therefore, it can be said that the contribution of the dissolution rate of the resist film was low, and the low residual film rate was achieved due to the contribution of the solubility of the resist film.

The compounds 1, 2, and 4 contained cyclohexene carboxylate, but it was confirmed that the compounds 1 and 2 were less likely to be insolubilized due to the presence of the carboxylate ligand of the second component. In particular, insolubilization of the compound 1 due to baking was not confirmed whatsoever, and thus it can be said that the compound 1 exhibited high process stability. This is considered to be because the partial introduction of 2-ethylhexanoate improved the hydrophobicity of the cluster compound, thereby strengthening the water resistance of the cluster compound, and also increased the amorphous property and thereby improved the solubility.

1. A transition metal cluster compound, comprising:
2 or more and 20 or less transition metal atoms, and
two or more types of carboxy ligands,
wherein at least one type of the carboxy ligands comprises an alicyclic structure having a double bond, and the transition metal cluster compound optionally comprises oxygen and/or a hydroxyl group.

2. The transition metal cluster compound according to claim 1, wherein the at least one type of the carboxy ligands including an alicyclic structure having a double bond is a ligand represented by the following General Formula (1): 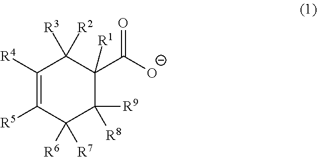
wherein in Formula (1), R¹ represents hydrogen, a halogen, a heteroatom-containing group, or a hydrocarbon group, and R² to R⁹ each independently represent hydrogen, a halogen, a heteroatom-containing group, or an organic group.

3. The transition metal cluster compound according to claim 1, wherein the at least one type of the carboxy ligands including an alicyclic structure having a double bond is a ligand represented by the following General Formula (2): 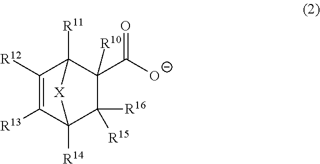
wherein in Formula (2), R¹⁰ represents hydrogen, a halogen, a heteroatom-containing group, or a hydrocarbon group; R¹¹ to R¹⁶ each independently represent hydrogen, a halogen, a heteroatom-containing group, or an organic group; and X represents oxygen or an alkyl bridge.

4. The transition metal cluster compound according to claim 1, wherein one type of the two or more types of carboxy ligands is the carboxy ligand including an alicyclic structure having a double bond and is represented by General Formula (1) or General Formula (2), and another one type of the two or more types of carboxy ligands is a carboxy ligand having a saturated hydrocarbon group.

5. The transition metal cluster compound according to claim 1, wherein one type of the two or more types of carboxy ligands is the carboxy ligand including an alicyclic structure having a double bond and is represented by General Formula (1) or General Formula (2), and another one type of the two or more types of carboxy ligands includes a carboxy ligand having a branched saturated hydrocarbon group.

6. The transition metal cluster compound according to claim 1, wherein the transition metal atoms are selected from zirconium, hafnium, and titanium.

7. A method for producing the transition metal cluster compound according to claim 1, the method comprising:
reacting a solution containing the transition metal compound with a carboxylic acid having a structure represented by General Formula (1) or General Formula (2).

8. The method for producing the transition metal cluster compound according to claim 7, wherein the solution containing a transition metal compound is a solution containing a transition metal alkoxide compound.

9. The method for producing the transition metal cluster compound according to claim 7, wherein the solution containing a transition metal compound is a solution containing a transition metal chloride.

10. A photosensitive composition, comprising:
the transition metal cluster compound according to claim 1.

11. The photosensitive composition according to claim 10, wherein the photosensitive composition reacts by light having a wavelength of from 6 nm to 15 nm.

12. A pattern forming method, comprising:
applying the photosensitive composition according to claim 10 onto a substrate;
exposing with actinic radiation; and
developing the photosensitive composition.

13. A pattern forming method, comprising:
applying the photosensitive composition according to claim 10 onto a substrate;
exposing with actinic radiation; and
developing the photosensitive composition with a developer.

14. The pattern forming method according to claim 13, wherein the developer comprises an organic solvent having a solubility parameter (SP value) of 7.5 to 11.

15. A substrate, comprising:
a patterned layer obtained by the pattern forming method according to claim 12.

16. A method for producing a substrate having a patterned layer obtained by the pattern forming method according to claim 12.
